(19) United States
(12) Patent Application Publication
(10) Pub. No.: US 2026/0214878 A1
(43) Pub. Date: Jul. 23, 2026

(54) MANUFACTURING METHOD OF SEMICONDUCTOR STRUCTURE

(71) Applicant: Winbond Electronics Corp., Taichung City (TW)

(72) Inventors: Meng-Wei Kao, Kaohsiung City (TW); Shu-Ming Li, Kaohsiung City (TW)

(73) Assignee: Winbond Electronics Corp., Taichung City (TW)

(21) Appl. No.: 19/047,664

(22) Filed: Feb. 7, 2025

(30) Foreign Application Priority Data
Jan. 22, 2025 (TW) 114102848

(51) Int. Cl. H10B 12/00; H10D 64/01

(52) U.S. Cl. CPC H10B 12/0335; H10B 12/482; H10D 64/015; H10D 64/021

(57) ABSTRACT

A manufacturing method of a semiconductor structure including the following steps is provided. A substrate is provided. Stack structures are formed on the substrate. The stack structures are separated from each other. First spacers are formed on sidewalls of the stack structures. Second spacers are formed on the first spacers. Spacer layers are formed on the second spacers. First dielectric layers are formed on the spacer layers. A portion of the second spacers and a portion of the first dielectric layers are removed to form first openings above the second spacers and to form second openings above the first dielectric layers. Cap layers are formed. The cap layers fill the first openings.

### CROSS-REFERENCE TO RELATED APPLICATION

This application claims the priority benefit of Taiwan application serial no. 114102848, filed on January 22, 2025. The entirety of the above-mentioned patent application is hereby incorporated by reference herein and made a part of this specification.

### BACKGROUND

### Technical Field

The invention relates to a manufacturing method of a semiconductor structure, and particularly relates to a manufacturing method of a semiconductor structure capable of preventing short circuit.

### Description of Related Art

In the semiconductor devices, the landing pad is used as the electrical connection component. However, during the process of forming the landing pads, the short circuit often occur between the conductive components. For example, in the process of forming the landing pads, the short circuit often occur between two adjacent landing pads.

### SUMMARY

The invention provides a manufacturing method of a semiconductor structure, which can prevent the short circuit between the conductive components.

The invention provides a manufacturing method of a semiconductor structure, which includes the following steps. A substrate is provided. Stack structures are formed on the substrate. The stack structures are separated from each other. First spacers are formed on sidewalls of the stack structures. Second spacers are formed on the first spacers. Spacer layers are formed on the second spacers. First dielectric layers are formed on the spacer layers. A portion of the second spacers and a portion of the first dielectric layers are removed to form first openings above the second spacers and to form second openings above the first dielectric layers. Cap layers are formed. The cap layers fill the first openings.

Based on the above description, in the manufacturing method of the semiconductor structure according to the invention, the cap layers fill the first openings, so that the cap layers can at least be used to protect the second spacers. In this way, in the subsequent process of forming the landing pad, the spacer structure located on the sidewall of the stack structure can have a smoother surface profile and a more complete structure. Therefore, in the subsequent process of forming the landing pads, since the spacer structure can have a smoother surface profile, the material layer used to form the landing pads can be effectively patterned to form the landing pads separated from each other, thereby effectively preventing the short circuit between two adjacent landing pads. In addition, in the subsequent process of forming the landing pads, since the spacer structure can have a more complete structure, other conductive components (e.g., the contact and the bit line) can be effectively isolated from each other to prevent the short circuit between other conductive components (e.g., between the contact and the bit line).

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1I are cross-sectional views of a manufacturing process of a semiconductor structure according to some embodiments of the invention.

FIG. 2A to FIG. 2D are cross-sectional views of a manufacturing process of a semiconductor structure according to some embodiments of the invention.

### DESCRIPTION OF THE EMBODIMENTS

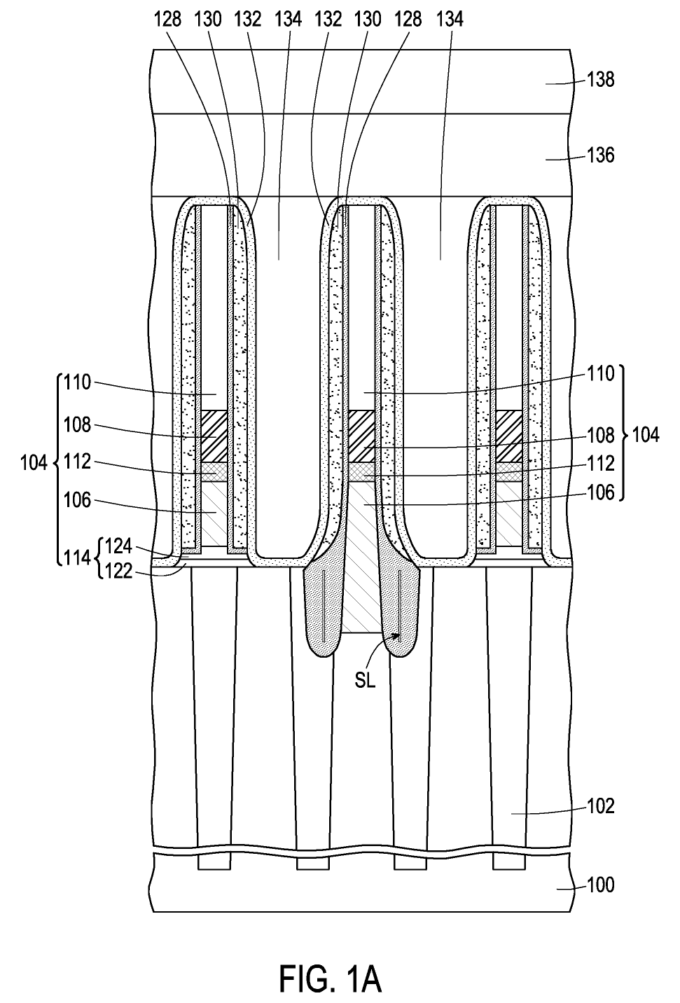

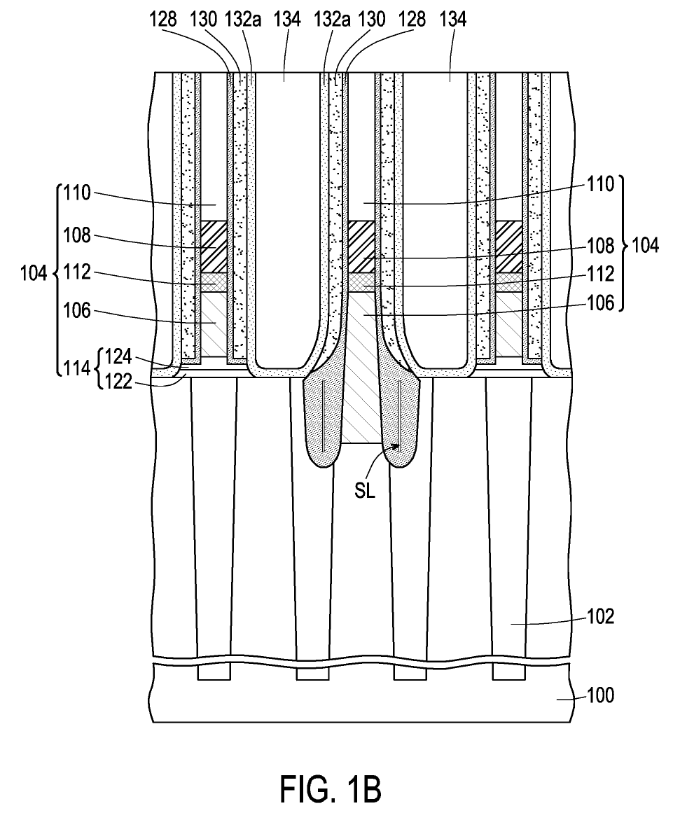

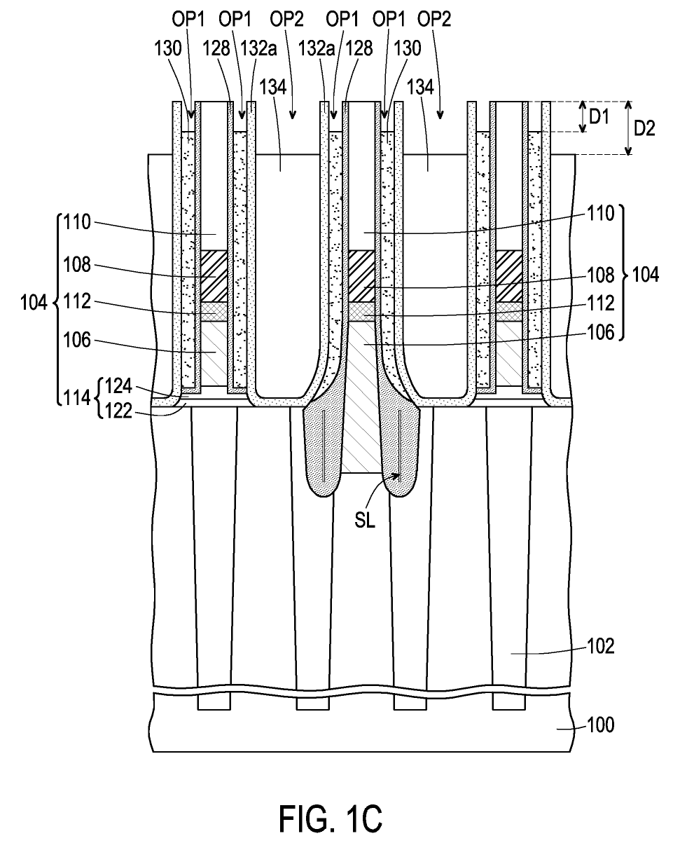

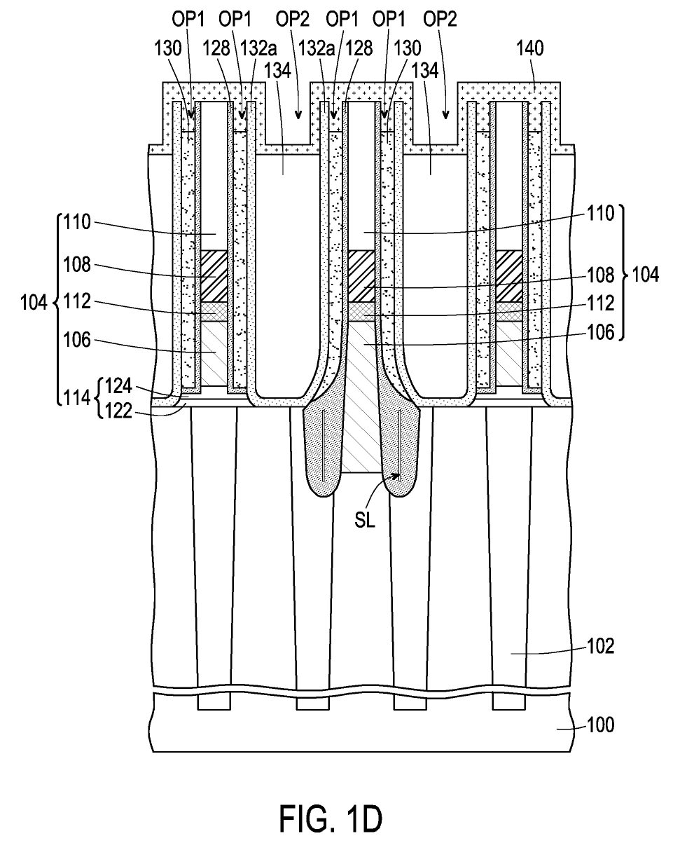

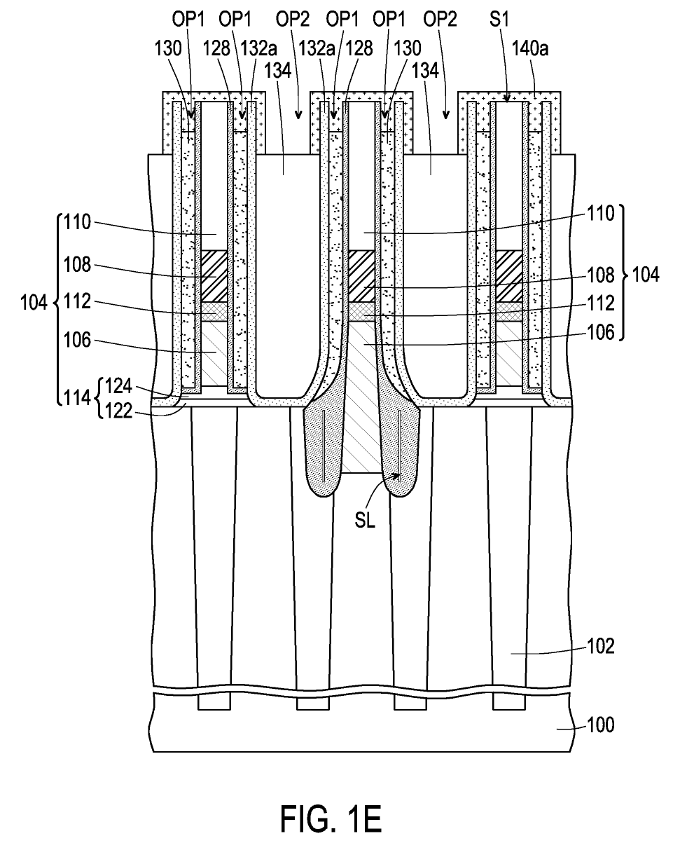

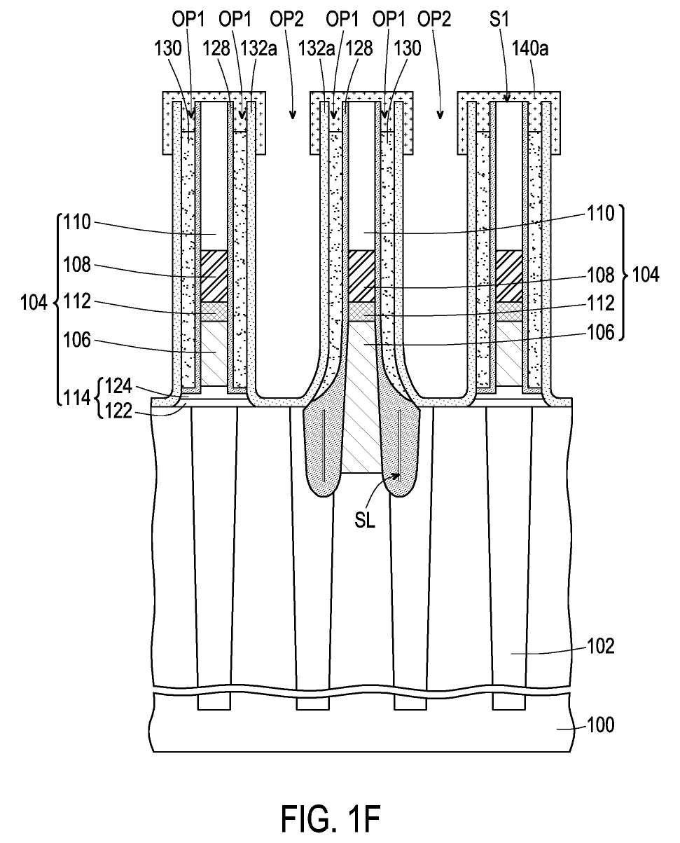

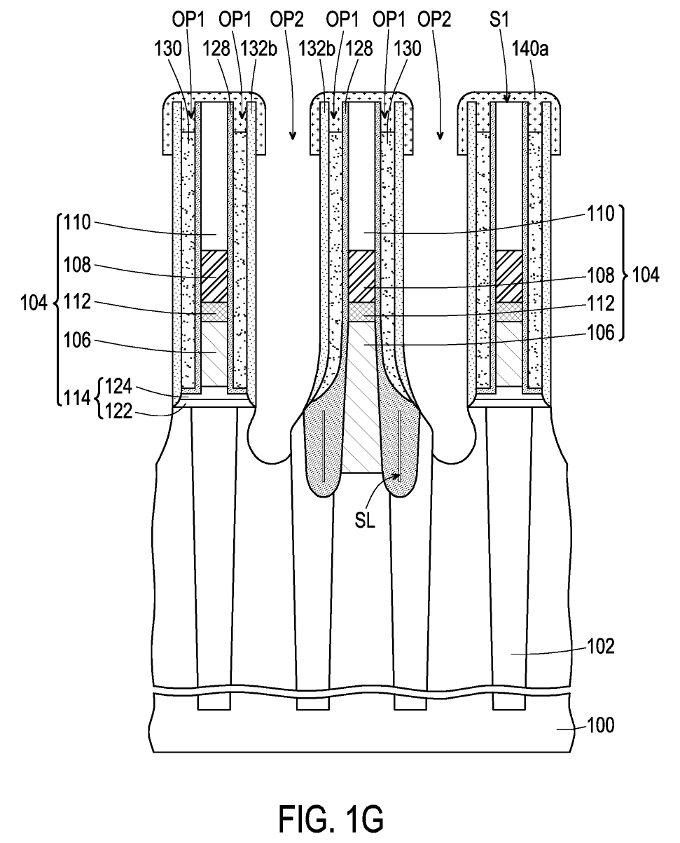

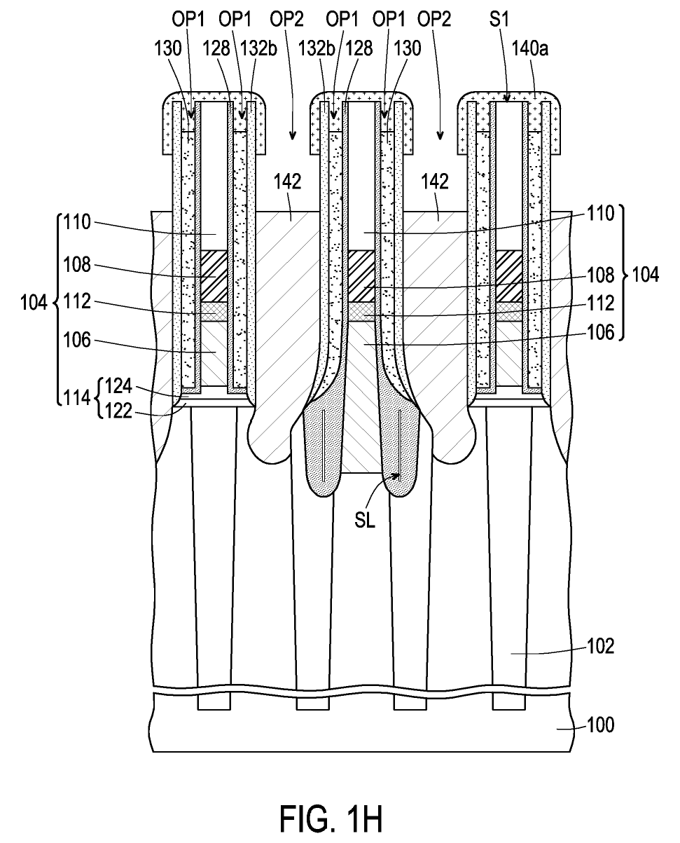

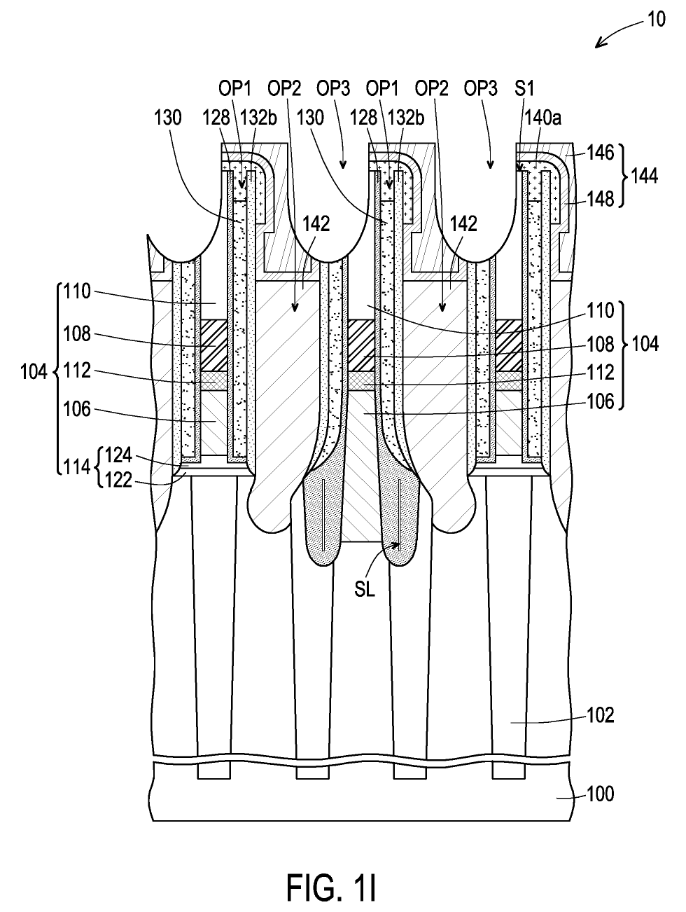

FIG. 1A to FIG. 1I are cross-sectional views of a manufacturing process of a semiconductor structure according to some embodiments of the invention.

Referring to FIG. 1A, a substrate 100 is provided. The substrate 100 may be a semiconductor substrate such as a silicon substrate. Furthermore, an isolation structure 102 may be formed in the substrate 100. The isolation structure 102 may be a shallow trench isolation structure. The material of the isolation structure 102 is, for example, silicon oxide. In addition, although not shown in the figure, other required component (e.g., doped region and/or buried word line structure) may be formed in the substrate 100.

Stack structures 104 are formed on the substrate 100. The stack structures 104 are separated from each other. The stack structures 104 may include bit line stack structures. The stack structure 104 (e.g., bit line stack structure) may include a conductive layer 106, a bit line 108, and a hard mask layer 110. The conductive layer 106 is located on the substrate 100 and has a portion in contact with the substrate 100. The portion of the conductive layer 106 that contacts the substrate 100 may be used as a bit line contact. The material of the conductive layer 106 is, for example, a conductive material such as doped polysilicon. The bit line 108 is located on the conductive layer 106. The material of the bit line 108 is, for example, a conductive material such as tungsten. The hard mask layer 110 is located on the bit line 108. The hard mask layer 110 may be a single-layer structure or a multilayer structure. The material of the hard mask layer 110 is, for example, silicon nitride. The stack structure 104 (e.g., bit line stack structure) may further include a barrier layer 112. The barrier layer 112 is located between the conductive layer 106 and the bit line 108. The material of the barrier layer 112 is, for example, titanium, titanium nitride, or a combination thereof.

The stack structure 104 (e.g., bit line stack structure) may further include a dielectric layer 114. The dielectric layer 114 is located on the substrate 100. The dielectric layer 114 may be located on the isolation structure 102. The dielectric layer 114 is located between the conductive layer 106 and the substrate 100. The dielectric layer 114 may be located between the conductive layer 106 and the isolation structure 102. The dielectric layer 114 may be a single-layer structure or a multilayer structure. In the present embodiment, the dielectric layer 114 may include a dielectric layer 122 and a dielectric layer 124. The dielectric layer 122 is located on the substrate 100. The material of the dielectric layer 122 is, for example, silicon oxide. The dielectric layer 124 is located on the dielectric layer 122. The material of the dielectric layer 124 is, for example, silicon nitride.

Spacers 128 are formed on the sidewalls of the stack structures 104. The spacer 128 may be a single-layer structure or a multilayer structure. In some embodiments, there may be a slit SL in the spacer 128. The material of the spacer 128 is, for example, silicon oxycarbide (SiCO), silicon nitride, or a combination thereof. Spacers 130 are formed on the spacers 128. The material of the spacer 130 is, for example, silicon oxide. A spacer material layer 132 may be formed on the spacers 128, the spacers 130, the stack structures 104, and the substrate 100. The material of the spacer material layer 132 is, for example, silicon nitride.

Dielectric layers 134 may be formed on the spacer material layer 132. The dielectric layer 134 may be located between two adjacent stack structures 104. The material of the dielectric layer 134 is, for example, silicon oxide. In some embodiments, a dielectric layer 136 may be formed on the spacer material layer 132 and the dielectric layer 134. The material of the dielectric layer 136 is, for example, silicon oxide. In some embodiments, a dielectric layer 138 may be formed on the dielectric layer 136. The material of the dielectric layer 138 is, for example, silicon nitride.

Referring to FIG. 1B, an etch-back process is performed to remove a portion of the spacer material layer 132 to form spacer layers 132a and to expose the spacers 130. Therefore, the spacer layers 132a may be formed on the spacers 130, and the dielectric layers 134 may be formed on the spacer layers 132a. The cross-sectional shape of the spacer layer 132a may be a U-shape. In the etch-back process, the dielectric layer 138, the dielectric layer 136, a portion of the spacers 128, a portion of the spacers 130, a portion of the stack structures 104 (e.g., a portion of the hard mask layers 110), and a portion of the dielectric layers 134 may be removed simultaneously. The etch-back process is, for example, a dry etching process.

Referring to FIG. 1C, a portion of the spacers 130 and a portion of the dielectric layers 134 are removed to form openings OP1 above the spacers 130 and to form openings OP2 above the dielectric layers 134. The depths D1 of the openings OP1 may be smaller than the depths D2 of the openings OP2. The method of removing a portion of the spacers 130 and a portion of the dielectric layers 134 is, for example, a wet etching method.

Referring to FIG. 1D, a capping material layer 140 is formed on the spacers 128, the spacers 130, the spacer layers 132a, the stack structures 104, and the dielectric layers 134. The capping material layer 140 may fill the openings OP1. The capping material layer 140 may be conformally formed in the openings OP2. The material of the capping material layer 140 is, for example, silicon nitride. The method of forming the capping material layer 140 is, for example, an atomic layer deposition (ALD) method.

Referring to FIG. 1E, an etch-back process is performed on the capping material layer 140 to form cap layers 140a. The cap layers 140a fill the openings OP1. In the present embodiment, the cap layers 140a may cover the top surfaces S1 of the stack structures 104. The etch-back process is, for example, a dry etching process.

Referring to FIG. 1F, the dielectric layers 134 may be removed. The method of removing the dielectric layers 134 is, for example, a wet etching method.

Referring to FIG. 1G, a portion of the spacer layers 132a may be removed to form spacers 132b and to expose the substrate 100 by the openings OP2. In some embodiments, in the process of removing the portion of the spacer layers 132a, a portion of the cap layers 140a may be removed. The method of removing the portion of the spacer layers 132a is, for example, a dry etching method. A portion of the substrate 100 may be removed so that the openings OP2 extend into the substrate 100. The method of removing the portion of the substrate 100 is, for example, a dry etching method.

Referring to FIG. 1H, contacts 142 may be formed in the openings OP2. The material of the contact 142 is, for example, a conductive material such as doped polysilicon. In some embodiments, the method of forming the contacts 142 may include the following steps. First, a contact material layer (not shown) filling the opening OP2 is formed. Then, a portion of the contact material layer is removed to form the contacts 142. The method of removing the portion of the contact material layer is, for example, an etch-back method (e.g., dry etching method).

Referring to FIG. 1I, landing pads 144 may be formed on the contacts 142. There may be an opening OP3 on one side of the landing pad 144. The landing pad 144 may be a single-layer structure or a multilayer structure. In the present embodiment, the landing pad 144 may include a conductive layer 146 and a barrier layer 148. The conductive layer 146 is located on the contact 142. The barrier layer 148 is located between the conductive layer 146 and the contact 142. The material of the conductive layer 146 is, for example, a conductive material such as tungsten. The material of the barrier layer 148 is, for example, titanium, titanium nitride, or a combination thereof.

In some embodiments, the method of forming the conductive layer 146, the barrier layer 148, and the opening OP3 may include the following steps. First, a material layer (not shown) for forming the barrier layer 148 and a material layer (not shown) for forming the conductive layer 146 may be sequentially formed. Next, the material layer for forming the conductive layer 146 and the material layer for forming the barrier layer 148 are patterned to form the conductive layer 146, the barrier layer 148, and the opening OP3. In the patterning process, the material layer for forming the conductive layer 146 and the material layer for forming the barrier layer 148 may be patterned by a lithography process and an etching process (e.g., dry etching process).

In subsequent processes, other required component (e.g., capacitor) may be formed to complete the fabrication of the semiconductor device (e.g., memory device), and the description thereof is omitted here.

Based on the above embodiments, in the manufacturing method of the semiconductor structure 10, the cap layers 140a fill the openings OP1, so that the cap layers 140a can at least be used to protect the spacers 130. In this way, in the subsequent process of forming the landing pad 144, the spacer structure (e.g., the spacers 128, 130, and 132b) located on the sidewall of the stack structure 104 can have a smoother surface profile and a more complete structure. Therefore, in the subsequent process of forming the landing pads 144, since the spacer structure (e.g., the spacers 128, 130, and 132b) can have a smoother surface profile, the material layer used to form the landing pads 144 can be effectively patterned to form the landing pads 144 separated from each other, thereby effectively preventing the short circuit between two adjacent landing pads 144. In addition, in the subsequent process of forming the landing pads 144, since the spacer structure (e.g., the spacers 128, 130, and 132b) can have a more complete structure, other conductive components (e.g., the contact 142 and the bit line 108) can be effectively isolated from each other to prevent the short circuit between other conductive components (e.g., between the contact 142 and the bit line 108).

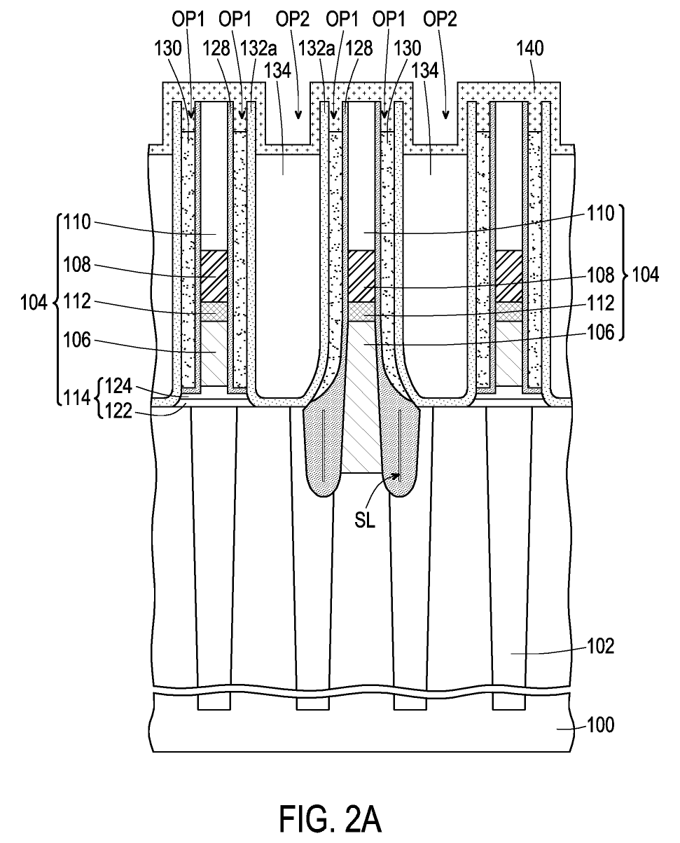

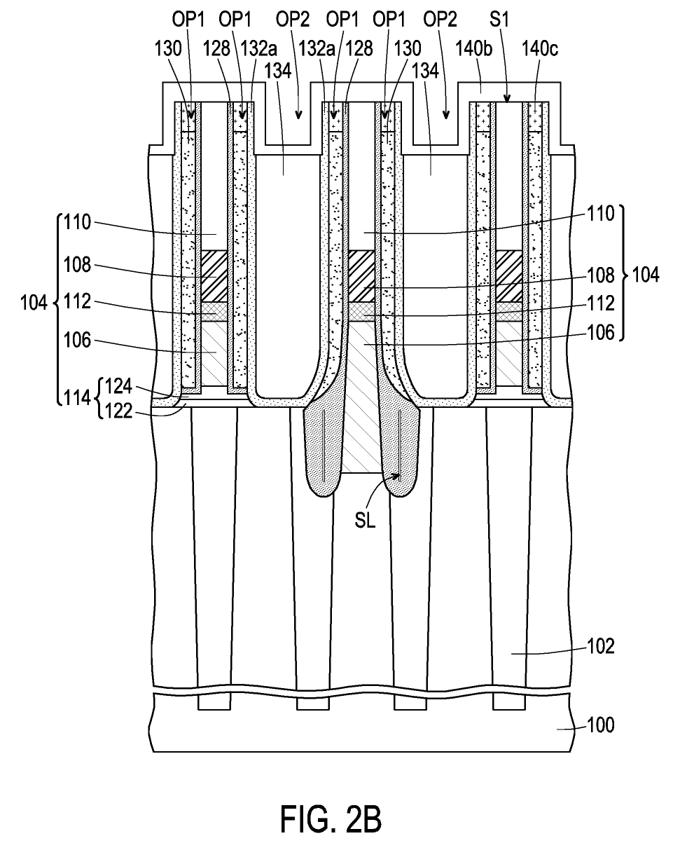

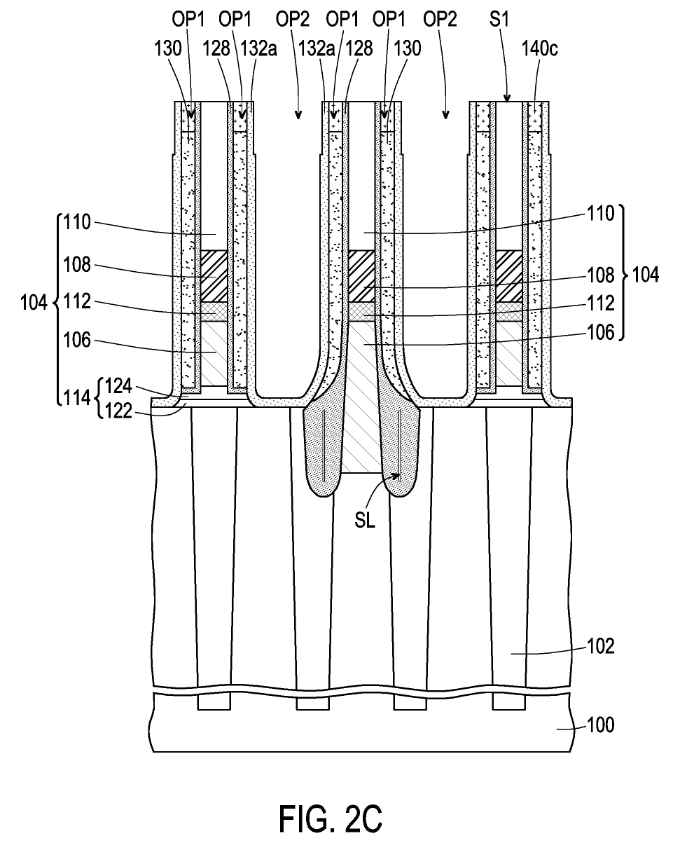

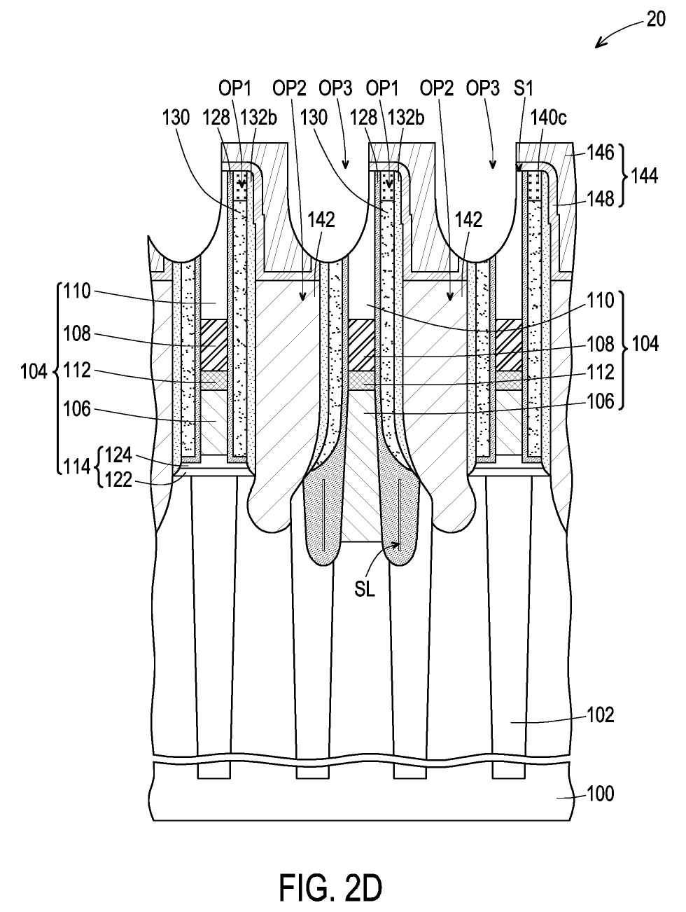

FIG. 2A to FIG. 2D are cross-sectional views of a manufacturing process of a semiconductor structure according to some embodiments of the invention.

Referring to FIG. 2A, a structure as shown in FIG. 1D is provided. In addition, the structure of FIG. 1D and the manufacturing method thereof have been described in detail in the above embodiments, and the description thereof is not repeated here.

Referring to FIG. 2B, an oxidation process is performed on the capping material layer 140 to form an oxide layer 140b and cap layers 140c. In some embodiments, a portion of the spacer layer 132a may be oxidized to become a portion of the oxide layer 140b. The cap layers 140c fill the openings OP1. In the present embodiment, the cap layers 140c may not cover the top surfaces S1 of the stack structures 104.

Referring to FIG. 2C, the oxide layer 140b may be removed. In the process of removing the oxide layer 140b, the dielectric layers 134 may be removed simultaneously. The method of removing the oxide layer 140b and the dielectric layers 134 is, for example, a wet etching method.

Referring to FIG. 2D, the steps as shown in FIG. 1G to FIG. 1I may be performed to form a semiconductor structure 20 of FIG. 2D. In addition, in the semiconductor structure 20 of FIG. 2D and the semiconductor structure 10 of FIG. 1I, the same or similar components are denoted by the same reference symbols, and the description thereof is omitted.

In subsequent processes, other required component (e.g., capacitor) may be formed to complete the fabrication of the semiconductor device (e.g., memory device), and the description thereof is omitted here.

In summary, in the manufacturing method of the semiconductor structure of the aforementioned embodiments, the spacer can be protected by the cap layer. In this way, in the subsequent process of forming the landing pads, the spacer structure located on the sidewall of the stack structure can have a smoother surface profile and a more complete structure. Therefore, in the subsequent process of forming the landing pads, the short circuit between two adjacent landing pads and the short circuit between other conductive components (e.g., between the contact and the bit line) can be effectively prevented.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A manufacturing method of a semiconductor structure, comprising:
providing a substrate;
forming stack structures on the substrate, wherein the stack structures are separated from each other;
forming first spacers on sidewalls of the stack structures;
forming second spacers on the first spacers;
forming spacer layers on the second spacers;
forming first dielectric layers on the spacer layers;
removing a portion of the second spacers and a portion of the first dielectric layers to form first openings above the second spacers and to form second openings above the first dielectric layers; and
forming cap layers, wherein the cap layers fill the first openings.

2. The manufacturing method of the semiconductor structure according to claim 1, wherein depths of the first openings are smaller than depths of the second openings.

3. The manufacturing method of the semiconductor structure according to claim 1, wherein a method of removing the portion of the second spacers and the portion of the first dielectric layers comprises a wet etching method.

4. The manufacturing method of the semiconductor structure according to claim 1, wherein a method of forming the spacer layers comprises:
forming a spacer material layer on the first spacers, the second spacers, the stack structures, and the substrate;
forming the first dielectric layers on the spacer material layer; and
performing an etch-back process to remove a portion of the spacer material layer to form the spacer layers and to expose the second spacers.

5. The manufacturing method of the semiconductor structure according to claim 4, wherein
in the etch-back process, a portion of the first spacers, a portion of the second spacers, a portion of the stack structures, and a portion of the first dielectric layers are removed simultaneously.

6. The manufacturing method of the semiconductor structure according to claim 4, wherein the etch-back process comprises a dry etching process.

7. The manufacturing method of the semiconductor structure according to claim 1, wherein a method of forming the cap layers comprises:
forming a capping material layer on the first spacers, the second spacers, the spacer layers, the stack structures, and the first dielectric layers, wherein the capping material layer fills the first openings; and
performing an etch-back process on the capping material layer to form the cap layers.

8. The manufacturing method of the semiconductor structure according to claim 7, wherein the cap layers cover top surfaces of the stack structures.

9. The manufacturing method of the semiconductor structure according to claim 7, wherein the etch-back process comprises a dry etching process.

10. The manufacturing method of the semiconductor structure according to claim 1, wherein a method of forming the cap layers comprises:
forming a capping material layer on the first spacers, the second spacers, the spacer layers, the stack structures, and the first dielectric layers, wherein the capping material layer fills the first openings; and
performing an oxidation process on the capping material layer to form an oxide layer and the cap layers.

11. The manufacturing method of the semiconductor structure according to claim 10, further comprising:
removing the oxide layer.

12. The manufacturing method of the semiconductor structure according to claim 11, wherein
in the process of removing the oxide layer, the first dielectric layers are removed simultaneously.

13. The manufacturing method of the semiconductor structure according to claim 12, wherein a method of removing the oxide layer and the first dielectric layers comprises a wet etching method.

14. The manufacturing method of the semiconductor structure according to claim 10, wherein the cap layers do not cover top surfaces of the stack structures.

15. The manufacturing method of the semiconductor structure according to claim 1, further comprising:
removing the first dielectric layers;
removing a portion of the spacer layers to form third spacers and to expose the substrate by the second openings; and
forming contacts in the second openings.

16. The manufacturing method of the semiconductor structure according to claim 15, further comprising:
before forming the contacts, removing a portion of the substrate so that the second openings extend into the substrate.

17. The manufacturing method of the semiconductor structure according to claim 15, wherein a method of removing the portion of the spacer layers comprises a dry etching method.

18. The manufacturing method of the semiconductor structure according to claim 1, wherein the stack structures comprise bit line stack structures.

19. The manufacturing method of the semiconductor structure according to claim 18, wherein each of the bit line stack structures comprises:
a conductive layer located on the substrate and having a portion in contact with the substrate;
a bit line located on the conductive layer; and
a hard mask layer located on the bit line.

20. The manufacturing method of the semiconductor structure according to claim 18, wherein each of the bit line stack structure further comprises:
a second dielectric layer located between the conductive layer and the substrate.
